(19) United States
(12) Patent Application Publication
(10) Pub. No.: US 2026/0112583 A1
(43) Pub. Date: Apr. 23, 2026

(54) UPPER TOP PLATE AND SUBSTRATE PROCESSING APPARATUS

(71) Applicant: Tokyo Electron Limited, Tokyo (JP)

(72) Inventors: Akiyoshi MITSUMORI, Miyagi (JP); Ryou SON, Miyagi (JP)

(73) Assignee: Tokyo Electron Limited, Tokyo (JP)

(21) Appl. No.: 19/426,553

(22) Filed: Dec. 19, 2025

Related U.S. Application Data
(63) Continuation of application No. PCT/JP2024/021444, filed on Jun. 13, 2024.

(30) Foreign Application Priority Data
Jun. 27, 2023 (JP) 2023-104986

(51) Int. Cl. H01J 37/32

(52) U.S. Cl. CPC H01J 37/32522; H01J 37/32568; H01J 2237/002

(57) ABSTRACT

An upper top plate is an upper top plate arranged at an upper part of a chamber, and the upper top plate includes a base, an upper electrode that is located on a lower surface side of the base, and a thermally conductive medium that is in a heat transfer space that is located between a lower surface of the base and an upper surface of the upper electrode and being surrounded by a sealing structure, in which a buffer space communicating with the heat transfer space is on the lower surface of the base in contact with the heat transfer space, and the thermally conductive medium is also partially in the buffer space.

### CROSS-REFERENCE TO RELATED APPLICATIONS

This application is a continuation application of International Application PCT/JP2024/021444, filed on Jun. 13, 2024, and designating the U.S., the international application being based upon and claiming the benefit of priority from Japanese Patent Application No. 2023-104986, filed on Jun. 27, 2023, the entire contents of each of which are incorporated herein by reference.

### FIELD

The present disclosure relates to an upper top plate and a substrate processing apparatus.

### BACKGROUND

It has been disclosed that, in an electrode assembly, a thermally conductive gasket includes a composite of aluminum foil coated with thermally and electrically conductive rubber, and that the thermally conductive gasket includes a carbon nanotube filler (Patent Literature 1).
Patent Literature 1: U.S. Pat. No. 8,216,418

The present disclosure provides an upper top plate and a substrate processing apparatus that are capable of maintaining favorable thermal conduction even when a base is deformed due to heat input.

### SUMMARY

According to an aspect of a present disclosure, there is provided an upper top plate arranged at an upper part of a chamber, the upper top plate including: a base; an upper electrode that is located on a lower surface side of the base; and a thermally conductive medium that is in a heat transfer space that is located between a lower surface of the base and an upper surface of the upper electrode and being surrounded by a sealing structure, wherein a buffer space communicating with the heat transfer space is on the lower surface of the base in contact with the heat transfer space, and the thermally conductive medium is also partially in the buffer space.

### BRIEF DESCRIPTION OF DRAWINGS

The scope of the present disclosure is best understood from the following detailed description of exemplary embodiments when read in conjunction with the accompanying drawings.

FIG. 1 is a diagram illustrating an example of a plasma processing apparatus according to an embodiment of the present disclosure.

FIG. 2 is a perspective view illustrating an example of an upper electrode according to the present embodiment.

FIG. 3 is a cross-sectional view illustrating an example of a heat transfer space according to the present embodiment.

FIG. 4 is a cross-sectional view illustrating another example of the heat transfer space according to the present embodiment.

FIG. 5 is a cross-sectional view illustrating an example of a state of the heat transfer space upon deformation according to the present embodiment.

FIG. 6 is a cross-sectional view illustrating another example of a buffer space according to the present embodiment.

FIG. 7 is a cross-sectional view illustrating another example of the buffer space according to the present embodiment.

### DESCRIPTION OF EMBODIMENT

Embodiments of an upper top plate and a substrate processing apparatus which are disclosed here will be described in detail below with reference to the drawings. It is noted that the technology disclosed herein is not limited by the following embodiments.

In a plasma processing apparatus, a chamber is provided at an upper part with an upper top plate having an upper electrode facing an inside of a chamber and a cooling plate (hereinafter also referred to as base) for cooling the upper electrode. A thermally conductive medium having favorable thermal conductivity, such as a heat transfer sheet (thermally conductive sheet), is provided between the upper electrode and the cooling plate, and heat input from plasma is transferred from the upper electrode to the cooling plate. However, with an increase in plasma power, an amount of heat input to each portion of the chamber increases, and an amount of deformation of the cooling plate, which deforms due to atmospheric pressure and heat input, has increased. When the cooling plate deforms, a portion may be generated where the thermally conductive medium provided between the upper electrode and the cooling plate is out of contact with the upper electrode and the cooling plate. Accordingly, thermal conduction between the upper electrode and the cooling plate is deteriorated. Therefore, it has been desired to maintain favorable thermal conduction even when the cooling plate (base) is deformed due to heat input.

### Configuration of Plasma Processing System

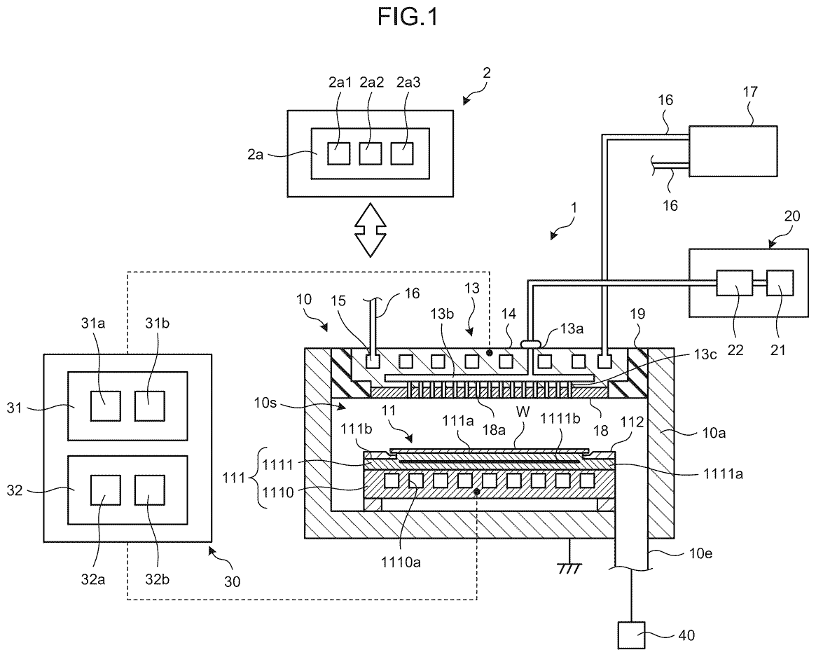

A configuration example of a plasma processing system will be described below. FIG. 1 is a diagram illustrating an example of a plasma processing apparatus according to an embodiment of the present disclosure. As illustrated in FIG. 1, the plasma processing system includes a capacitively coupled plasma processing apparatus 1 and a controller 2. The capacitively coupled plasma processing apparatus 1 includes a plasma processing chamber 10, a chiller unit 17, a gas supply unit 20, a power supply 30, and an exhaust system 40. The plasma processing apparatus 1 further includes a substrate support unit 11 and a gas introducing unit. The gas introducing unit is configured to introduce at least one processing gas into the plasma processing chamber 10. The gas introducing unit includes a showerhead 13. The substrate support unit 11 is arranged in the plasma processing chamber 10. The showerhead 13 is arranged above the substrate support unit 11. In an embodiment, the showerhead 13 constitutes at least a part of a ceiling of the plasma processing chamber 10. The plasma processing chamber 10 includes a plasma processing space 10s defined by the showerhead 13, a side wall 10a of the plasma processing chamber 10, and the substrate support unit 11. The plasma processing chamber 10 includes at least one gas supply port for supplying the at least one processing gas to the plasma processing space 10s, and at least one gas discharge port for discharging the gas from the plasma processing space 10s. The plasma processing chamber 10 is grounded. The showerhead 13 and the substrate support unit 11 are electrically insulated from a case of the plasma processing chamber 10.

The substrate support unit 11 includes a main unit 111 and a ring assembly 112. The main unit 111 includes a central region 111a for supporting a substrate W and an annular region 111b for supporting the ring assembly 112. A wafer is an example of the substrate W. In plan view, the annular region 111b of the main unit 111 surrounds the central region 111a of the main unit 111. The substrate W is placed on the central region 111a of the main unit 111, and the ring assembly 112 is arranged on the annular region 111b of the main unit 111 so as to surround the substrate W on the central region 111a of the main unit 111. Accordingly, the central region 111a is also referred to as substrate support surface for supporting the substrate W, and the annular region 111b is also referred to as ring support surface for supporting the ring assembly 112.

In an embodiment, the main unit 111 includes a base 1110 and an electrostatic chuck 1111. The base 1110 includes a conductive member. The conductive member of the base 1110 can function as a lower electrode. The electrostatic chuck 1111 is arranged on the base 1110. The electrostatic chuck 1111 includes a ceramic member 1111a and an electrostatic electrode 1111b arranged in the ceramic member 1111a. The ceramic member 1111a includes the central region 111a. In an embodiment, the ceramic member 1111a also includes the annular region 111b. It is noted that other members surrounding the electrostatic chuck 1111, such as an annular electrostatic chuck or an annular insulating member, may have the annular region 111b. In this configuration, the ring assembly 112 may be arranged on the annular electrostatic chuck or the annular insulating member, or may be arranged on both the electrostatic chuck 1111 and the annular insulating member. Furthermore, at least one RF/DC electrode coupled to a radio frequency (RF) power supply 31 and/or a direct current (DC) power supply 32, described later, may be arranged in the ceramic member 1111a. In this configuration, the at least one RF/DC electrode functions as the lower electrode. When a bias RF signal and/or a DC signal, which are described later, is supplied to the at least one RF/DC electrode, the RF/DC electrode is also referred to as bias electrode. It is noted that the conductive member of the base 1110 and the at least one RF/DC electrode may function as a plurality of the lower electrodes. Furthermore, the electrostatic electrode 1111b may function as the lower electrode. Accordingly, the substrate support unit 11 includes at least one lower electrode.

The ring assembly 112 includes one or a plurality of annular members. In an embodiment, the one or the plurality of annular members include one or a plurality of edge rings and at least one cover ring. Each of the one or the plurality of edge rings is formed of a conductive material or an insulating material, and the cover ring is formed of an insulating material.

The substrate support unit 11 may further include a temperature control module configured to control at least one of the electrostatic chuck 1111, the ring assembly 112, and the substrate to have a target temperature. The temperature control module may include a heater, a heat transfer medium, a channel 1110a, or a combination thereof. A heat transfer fluid such as brine or a gas flows through the channel 1110a. In an embodiment, the channel 1110a is formed in the base 1110, and one or a plurality of heaters are arranged in the ceramic member 1111a of the electrostatic chuck 1111. The substrate support unit 11 may further include a heat transfer gas supply unit configured to supply a heat transfer gas into a gap between a backside of the substrate W and the central region 111a.

The showerhead 13 is configured to introduce the at least one processing gas from the gas supply unit 20 into the plasma processing space 10s. The showerhead 13 is supported at an upper part of the plasma processing chamber 10 via an insulating shield member 19. The showerhead 13 includes a cooling plate (base) 14 and an upper electrode 18. The upper electrode 18 has a plurality of discharge holes 18a formed therethrough in a thickness direction for emitting the processing gas into the plasma processing chamber 10.

The cooling plate 14 is formed of a conductive material to removably support the upper electrode 18 at a lower part thereof. The cooling plate 14 has at least one gas supply port 13a, at least one gas diffusion chamber 13b, and a plurality of gas introduction ports 13c. Each of the plurality of gas introduction ports 13c communicates with each of the plurality of discharge holes 18a. The processing gas supplied to the gas supply port 13a is introduced into the plasma processing space 10s through the gas diffusion chamber 13b, and from the plurality of gas introduction ports 13c and the plurality of discharge holes 18a. It is noted that the gas introducing unit may further include one or a plurality of side gas injectors (SGIs) mounted to one or a plurality of openings formed in the side wall 10a, in addition to the showerhead 13.

Furthermore, a channel 15 is provided inside the cooling plate 14, and a refrigerant from the chiller unit 17 provided outside the plasma processing chamber 10 is supplied into the channel 15 via a pipe 16. The refrigerant supplied from the chiller unit 17 into the channel 15 of the cooling plate 14 via the pipe 16 circulates in the channel 15 and returns to the chiller unit 17 via the pipe 16. The chiller unit 17 controls a temperature of the refrigerant supplied into the channel 15. The chiller unit 17 is an example of a temperature controller. Circulation of the temperature-controlled refrigerant in the channel 15 suppresses a temperature rise of the showerhead 13 due to the heat input from plasma generated between the substrate support unit 11 and the showerhead 13. It is noted that the cooling plate 14 may suppress the temperature rise of the showerhead 13 by an air cooling method using heat exchange with ambient air outside the plasma processing chamber 10 without providing the channel on the inside, or by a water-cooling jacket, a Peltier element, or the like mounted on the outside.

The upper electrode 18 is formed of a conductive material such as silicon or SiC. It is noted that, instead of the upper electrode 18, a plate formed of a dielectric material, such as quartz or ceramic, and having a plurality of discharge holes formed to communicate with the plurality of gas introduction ports 13c may be removably supported at the lower part of the cooling plate 14.

The gas supply unit 20 may include at least one gas source 21 and at least one flow controller 22. In an embodiment, the gas supply unit 20 is configured to supply at least one processing gas to the showerhead 13, from a corresponding gas source 21, via a corresponding flow controller 22. Each flow controller 22 may include, for example, a mass flow controller or a pressure-controlled flow controller. Furthermore, the gas supply unit 20 may include one or more flow rate modulation devices that modulate or pulse a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Therefore, plasma is formed from at least one processing gas supplied to the plasma processing space 10s. Accordingly, the RF power supply 31 can function as at least part of a plasma generation unit configured to generate plasma from one or more processing gases in the plasma processing chamber 10. Furthermore, supplying the bias RF signal to the at least one lower electrode enables generation of a bias potential in the substrate W, and an ion component in the formed plasma can be attracted to the substrate W.

In an embodiment, the RF power supply 31 includes a first RF generation unit 31a and a second RF generation unit 31b. The first RF generation unit 31a is coupled to the at least one lower electrode and/or the at least one upper electrode via the at least one impedance matching circuit, and is configured to generate a source RF signal (source RF power) for plasma generation. In an embodiment, the source RF signal has a frequency in a range of 10 MHz to 150 MHz. In an embodiment, the first RF generation unit 31a may be configured to generate a plurality of the source RF signals having different frequencies. The generated one or plurality of the source RF signals is supplied to the at least one lower electrode and/or the at least one upper electrode.

The second RF generation unit 31b is coupled to the at least one lower electrode via at least one impedance matching circuit, and is configured to generate the bias RF signal (bias RF power). The bias RF signal may have a frequency the same as or different from the frequency of the source RF signal. In an embodiment, the frequency of the bias RF signal is lower than the frequency of the source RF signal. In an embodiment, the bias RF signal has a frequency in a range of 100 kHz to 60 MHz. In an embodiment, the second RF generation unit 31b may be configured to generate a plurality of the bias RF signals having different frequencies. The generated one or plurality of the bias RF signals is supplied to the at least one lower electrode. Furthermore, in various embodiments, at least one of the source RF signal and the bias RF signal may be pulsed.

The power supply 30 may further include a DC power supply 32 coupled to the plasma processing chamber 10. The DC power supply 32 includes a first DC generation unit 32a and a second DC generation unit 32b. In an embodiment, the first DC generation unit 32a is connected to the at least one lower electrode and is configured to generate a first DC signal. The generated first bias DC signal is applied to the at least one lower electrode. In an embodiment, the second DC generation unit 32b is connected to the at least one upper electrode and is configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. Each of the voltage pulses may have a pulse waveform that has a rectangular shape, trapezoidal shape, triangular shape, or combinations thereof. In an embodiment, a waveform generation unit for generating the sequence of voltage pulses from the DC signal is connected between the first DC generation unit 32a and the at least one lower electrode. Accordingly, the first DC generation unit 32a and the waveform generation unit constitute a voltage pulse generation unit. When the second DC generation unit 32b and the waveform generation unit constitute the voltage pulse generation unit, the voltage pulse generation unit is connected to the at least one upper electrode. The voltage pulses may have a positive polarity or may have a negative polarity. Furthermore, the sequence of voltage pulses may include one or a plurality of positive polarity voltage pulses and one or a plurality of negative polarity voltage pulses in one cycle. It is noted that the first and second DC generation units 32a and 32b may be provided in addition to the RF power supply 31, and the first DC generation unit 32a may be provided in place of the second RF generation unit 31b.

The exhaust system 40 can be connected to, for example, a gas discharge port 10e provided at a bottom part of the plasma processing chamber 10. The exhaust system 40 may include a pressure regulating valve and a vacuum pump. The pressure regulating valve regulates pressure in the plasma processing space 10s. The vacuum pump may include a turbomolecular pump, a dry pump, or a combination thereof.

The controller 2 (herein controller means the same as controller circuitry) processes computer-executable instructions that cause the plasma processing apparatus 1 to perform various processes described in the present disclosure. The controller 2 can be configured to control respective elements of the plasma processing apparatus 1 to perform various processes described herein. In an embodiment, part or all of the controller 2 may be included in the plasma processing apparatus 1. The controller 2 may include a processor 2a1, a storage 2a2, and a communication interface 2a3. The controller 2 is implemented by, for example, a computer 2a. The processor 2a1 can be configured to read a program from the storage 2a2 and to perform various control operations by executing the read program. The program may be stored in advance in the storage 2a2, or may be acquired via a medium when necessary. The acquired program is stored in the storage 2a2 and is read from the storage 2a2 by the processor 2a1 for execution. For the medium, various storage media readable by the computer 2a, or a communication line connected to the communication interface 2a3 may be used. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

### Details of Upper Electrode and Heat Transfer Space

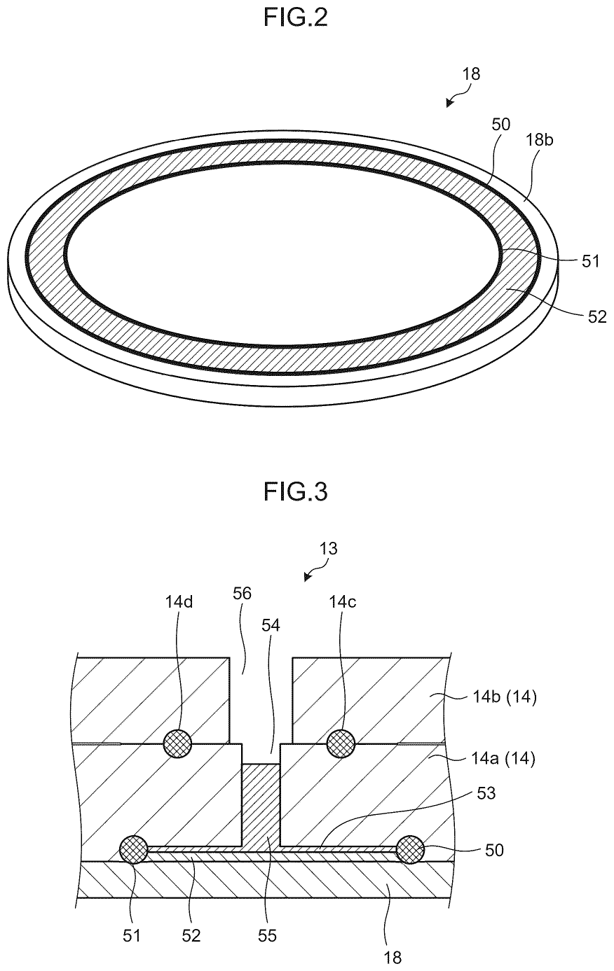

Next, the upper electrode 18 and the heat transfer space, and a state of the heat transfer space upon deformation of the cooling plate will be described with reference to FIGS. 2 to 5. FIG. 2 is a perspective view illustrating an example of the upper electrode according to the present embodiment. As illustrated in FIG. 2, an upper surface 18b of the upper electrode 18 in contact with the cooling plate 14 has an outer peripheral portion that is circumferentially provided with annular sealing members 50 and 51 having different diameters (herein sealing member means the same as sealing structure). The sealing member 51 is arranged on an inner circumferential side relative to the sealing member 50. The sealing members 50 and 51 are each, for example, a lip seal, and prevent deterioration in quality and consumption of the thermally conductive medium. A heat transfer sheet 52 is provided between the sealing member 50 and the sealing member 51. For the heat transfer sheet 52, for example, a heat transfer sheet of a silicone material, a metal material such as aluminum, graphite material, or a resin material can be used. It is noted that, in FIG. 2, the discharge holes 18a of the upper electrode 18 are not illustrated. However, the discharge holes 18a are shown in FIG. 1.

FIG. 3 is a cross-sectional view illustrating an example of the heat transfer space according to the present embodiment. In FIG. 3, of a cross-section showing a state where the upper electrode 18 is mounted on the cooling plate 14 in the showerhead 13, a vicinity of the sealing members 50 and 51 is illustrated. As illustrated in FIG. 3, in the present embodiment, the cooling plate 14 has a structure that can be divided into a lower member 14a and an upper member 14b. It is noted that the cooling plate 14 may have a structure in which the lower member 14a and the upper member 14b are integrated with each other. A heat transfer space 53 surrounded by the sealing members 50 and 51 is formed between a lower surface of the lower member 14a and an upper surface of the upper electrode 18. In the heat transfer space 53, the heat transfer sheet 52 illustrated in FIG. 2 is arranged. Furthermore, a buffer space 54 that communicates with the heat transfer space 53 is formed to a lower surface of the lower member 14a that is in contact with the heat transfer space 53. A through-hole 56 is formed in the upper member 14b so as to penetrate from an upper surface to a lower surface of the upper member 14b and communicate with the buffer space 54.

The heat transfer space 53 is filled with a fluid 55. The fluid 55 is filled in a gap between the heat transfer sheet 52 and the lower surface of the lower member 14a in the heat transfer space 53 and also partially filled in the buffer space 54 communicating with the heat transfer space 53. In other words, the heat transfer sheet 52 and the fluid 55 are an example of the thermally conductive medium. The fluid 55 is a liquid substance, and for the fluid 55, for example, a vacuum grease for heat transfer, having low volatility in a vacuum atmosphere, can be used. For the vacuum grease, for example, a vacuum grease of a silicone material, a fluorine material, or a metal material can be used. The fluid 55 is, for example, applied in advance between the sealing members 50 and 51 of the upper electrode 18 upon assembly of the showerhead 13. By pressing the upper electrode 18 against the cooling plate 14, the fluid 55 is filled in the heat transfer space 53 and partially extruded into the buffer space 54. It is noted that, after assembly of the showerhead 13, the fluid 55 may be filled in the heat transfer space 53 with the through-hole 56 communicating with the buffer space 54 of the upper member 14b and the buffer space 54 as an injection channel. It is noted that the through-hole 56 does not communicate with the gas diffusion chamber 13b and the gas introduction ports 13c. Furthermore, an upper part of the through-hole 56 is not being sealed by a cap.

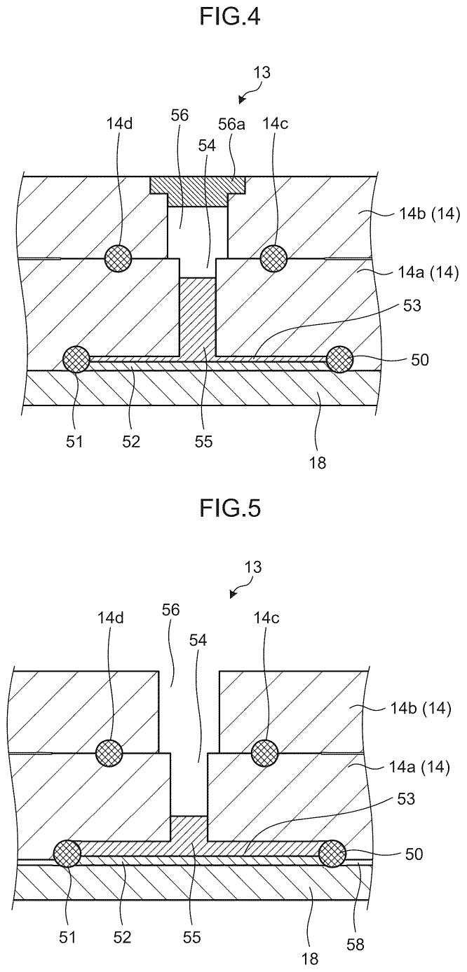

FIG. 4 is a cross-sectional view illustrating another example of the heat transfer space according to the present embodiment. The showerhead 13 of FIG. 4 shows a state in which the upper part of the through-hole 56 is being sealed by a cap 56a, in contrast with the showerhead 13 of FIG. 3. In other words, the through-hole 56 may be sealed or may not be sealed by the cap 56a. Furthermore, when the through-hole 56 is sealed by the cap 56a, it is preferable to provide a vent hole in the cap 56a or at another place of the upper member 14b, for ventilation of a gas such as air inside the buffer space 54 and the through-hole 56 to the outside when part of the fluid 55 is extruded into the buffer space 54.

The buffer space 54 has, for example, a slit shape or a hole shape, and the lower member 14a above the heat transfer space 53 having a ring shape is provided with a plurality of the buffer spaces 54. Here, the slit shape refers to a shape having a cross-section of elongated rectangular shape, arcuate shape, or the like when the cooling plate 14 is viewed from above. Furthermore, the hole shape refers to a shape having a cross-section of circular shape, square shape, or the like when the cooling plate 14 is viewed from above. At this time, the buffer spaces 54 may be provided, for example, at equal intervals on the circumference of the heat transfer space 53. It is noted that sealing members 14c and 14d for maintaining airtightness of the plasma processing space 10s are provided between the lower member 14a and the upper member 14b, respectively outside and inside the buffer space 54.

FIG. 5 is a cross-sectional view illustrating an example of a state of the heat transfer space upon deformation according to the present embodiment. FIG. 5 illustrates a vicinity of the sealing members 50 and 51 of the showerhead 13 with the cooling plate 14 deformed due to heat input from plasma. As illustrated in FIG. 5, at a peripheral edge portion of the showerhead 13, a gap 58 is generated due to deformation of the cooling plate 14, between the lower surface of the lower member 14a and the upper surface of the upper electrode 18. At this time, in the heat transfer space 53, the gap is generated as a space is extended vertically, but the fluid 55 filled in the buffer space 54 is filled in the gap by gravity. Furthermore, the heat input increases the temperature of the fluid 55 and reduces viscosity thereof, and therefore, the fluid 55 is readily filled in the gap. It is noted that the sealing members 50 and 51 perform sealing so that the fluid 55 may not leak to the outside even if the gap 58 is generated. Furthermore, the buffer space 54 and an atmospheric space above the upper surface of the upper member 14b have the same pressure, and therefore, movement of the fluid 55 is not hindered by pressure in the buffer space 54, and movement of the fluid 55 into the heat transfer space 53 is not inhibited.

With no heat input from plasma, the state of FIG. 5 returns to the state of FIG. 3. At this time, the deformation due to the heat input returns to the original form, and therefore, excess the fluid 55 returns from the heat transfer space 53 to the buffer space 54. In this way, in the present embodiment, even when the cooling plate 14 is deformed due to the heat input, an area of contact with the upper electrode 18 is maintained by the heat transfer sheet 52 and the fluid 55, positioned in the heat transfer space 53, and therefore, favorable thermal conduction can be maintained.

It is noted that, in the present embodiment, a deformation is assumed in which the center of the cooling plate 14 having a circular shape protrudes downward. Therefore, when the deformation occurs at a peripheral edge portion where the gap is generated between the cooling plate 14 and the upper electrode 18, the area of contact for heat transfer is secured in the heat transfer space 53 having the ring shape, surrounded by the sealing members 50 and 51. For example, it is assumed that approximately 50% of the areas of the lower surface of the cooling plate 14 and the upper surface of the upper electrode 18 is the area of contact between the cooling plate 14 and the upper electrode 18. In this configuration, heat transfer only by the heat transfer sheet is considerably reduced in heat transfer capability, when the area of contact changes to 10% due to deformation, and temperature of the upper electrode 18 cannot be maintained. In contrast, in the present embodiment, using the heat transfer sheet 52 and the fluid 55 together enables maintaining the area of contact of 50%. It is noted that when the fluid 55 has a high thermal conductivity, the heat transfer sheet 52 may be omitted from the thermally conductive medium so that only the fluid 55 is used.

In the examples of FIGS. 3 and 5, the buffer space 54 is in communication with the atmospheric space via the through-hole 56, but the configuration is not limited thereto. For example, the through-hole 56 may not be provided, and a gap or communication hole that communicates with the gas diffusion chamber 13b or the plasma processing space 10s may be provided. With this configuration, the buffer space 54 and the gas diffusion chamber 13b or the plasma processing space 10s have the same pressure, and therefore, movement of the fluid 55 is not hindered by pressure in the buffer space 54, and movement of the fluid 55 into the heat transfer space 53 is not inhibited. It is noted that when the buffer space 54 communicates with the gas diffusion chamber 13b or the plasma processing space 10s, the fluid 55 used preferably has no volatility or has very low volatility at the pressure of the gas diffusion chamber 13b or the plasma processing space 10s. Furthermore, when the through-hole 56 is not provided, after assembly of the showerhead 13, the fluid 55 may be filled in the heat transfer space 53, with the gap or the communication hole and the buffer space 54 that communicate with the gas diffusion chamber 13b or the plasma processing space 10s as the injection channel.

### Alternative Examples

In the above embodiment, the buffer space 54 has been formed to have a cross-sectional area that is constant over the entire vertical range, but the buffer space 54 may be formed to have a cross-sectional area increasing at an upper part or a lower part. This case will be described as alternative examples. It is noted that the plasma processing apparatus in the alternative examples has similar configurations to those in the embodiments described above, and descriptions of overlapping configurations and operations will not be repeated.

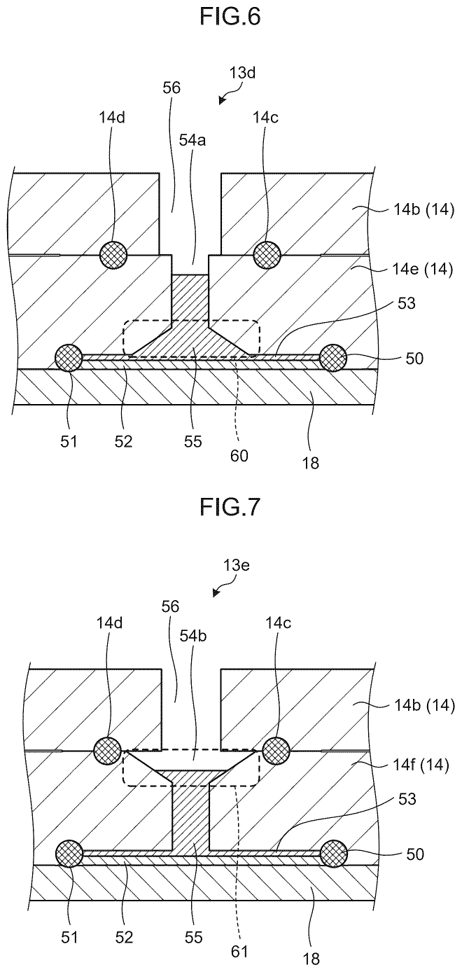

FIGS. 6 and 7 are cross-sectional views each illustrating another example of the buffer space according to the present embodiment. A showerhead 13d illustrated in FIG. 6 uses a lower member 14e in place of the lower member 14a. A buffer space 54a is formed in the lower member 14e. The buffer space 54a is formed to have a lower part (on a side of the heat transfer space 53) having a larger cross-sectional area than that at an upper part of the buffer space 54a, as shown in a region 60. It is noted that the region 60 may have a tapered shape or may have another shape such as a stepped shape. Providing the region 60 further facilitates filling of the fluid 55 in the buffer space 54a in the heat transfer space 53. Furthermore, it is possible to increase an amount of the fluid 55 stored in the heat transfer space 53 and the buffer space 54a.

A showerhead 13e illustrated in FIG. 7 uses a lower member 14f in place of the lower member 14a. A buffer space 54b is formed in the lower member 14f. The buffer space 54b is formed to have an upper part (on a side opposite to the heat transfer space 53) having a larger cross-sectional area than that at a lower part of the buffer space 54b, as shown in a region 61. It is noted that, Similarly to the region 60, the region 61 may have a tapered shape or may have another shape such as a stepped shape. Providing the region 61 makes it possible to increase an amount of the fluid 55 stored in the heat transfer space 53 and the buffer space 54b. It is noted that a radial width of the upper part of the buffer space 54b, that is, a radial width of the buffer space 54b at an upper surface of the lower member 14f, is formed smaller than a space between the sealing members 14c and 14d, and therefore, airtightness of the plasma processing space 10s can be maintained.

It is preferable to determine whether to use the lower member 14e of the showerhead 13d or the lower member 14f of the showerhead 13e depending on the thermal conductivity of the thermally conductive medium. For example, when the thermal conductivity of the heat transfer sheet 52 is smaller than the thermal conductivity of the fluid 55, it is preferable to use the lower member 14e. On the other hand, when the thermal conductivity of the heat transfer sheet 52 is greater than the thermal conductivity of the fluid 55, it is preferable to use the lower member 14f. In other words, when using the lower member 14f, contribution of the fluid 55 is reduced. It is noted that the lower member 14e and the lower member 14f may be combined to form the buffer space 54 to have the cross-sectional areas increasing at the upper part and the lower part.

It is noted that in the embodiment described above, the heat transfer space 53 has been formed into the ring shape, but the shape of the heat transfer space 53 is not limited thereto. For example, the heat transfer space 53 may be formed into a plurality of independent islands in a circumferential direction of the cooling plate 14 and the upper electrode 18. This configuration makes it possible to form the heat transfer space 53, readily avoiding a connection portion between the channel 15 and the pipe 16 in the cooling plate 14, the gas supply port 13a, and the like.

As described above, according to the present embodiment, the upper top plate (the showerhead 13) is an upper top plate arranged at the upper part of the chamber (the plasma processing chamber 10), and the upper top plate includes the base (the cooling plate 14), the upper electrode 18 that is arranged on a lower surface side of the base and faces the inside of the chamber, and the thermally conductive medium (the fluid 55) that is filled in the heat transfer space 53, provided between the lower surface of the base and the upper surface of the upper electrode 18 and surrounded by the sealing members 50 and 51. The base has the lower surface in contact with the heat transfer space 53 in which the buffer space 54 communicating with the heat transfer space 53 is formed, and the thermally conductive medium is also partially filled in the buffer space 54. As a result, it is possible to maintain favorable thermal conduction, even when the base is deformed due to heat input.

Furthermore, according to the present embodiment, the thermally conductive medium includes the liquid substance. As a result, even if deformation due to heat input is repeated, the thermally conductive medium is filled into the heat transfer space 53 each time of the deformation, and favorable thermal conduction can be maintained.

Furthermore, according to the present embodiment, the thermally conductive medium includes the heat transfer sheet 52 arranged in the heat transfer space 53. As a result, it is possible to reduce an amount of the fluid 55 required.

Furthermore, according to the present embodiment, the liquid substance is the vacuum grease. As a result, it is possible to suppress volatilization of the vacuum grease (the fluid 55), even when the buffer space 54 has the vacuum atmosphere.

Furthermore, according to the present embodiment, the buffer space 54 is connected to the injection channel (the through-hole 56) communicating with the outside of the base. As a result, it is possible to fill the fluid 55 in the heat transfer space 53, even after assembly of the showerhead 13.

Furthermore, according to the present embodiment, the injection channel communicates with the inside of the chamber. As a result, movement of the fluid 55 from the buffer space 54 to the heat transfer space 53 is not inhibited.

Furthermore, according to the present embodiment, the buffer space 54 has an internal pressure that changes according to an internal pressure of the chamber. As a result, movement of the fluid 55 from the buffer space 54 to the heat transfer space 53 is not inhibited.

Furthermore, according to the present embodiment, the buffer space 54 has a slit shape. As a result, it is possible to store the fluid 55.

Furthermore, according to the present embodiment, the buffer space 54 has a hole shape. As a result, it is possible to store the fluid 55.

Furthermore, according to the present embodiment, the buffer space 54a is formed to have a cross-sectional area larger on the side of the heat transfer space 53. As a result, it is further facilitated that the fluid 55 in the buffer space 54a is filled in the heat transfer space 53.

Furthermore, according to the present embodiment, the buffer space 54b is formed to have a cross-sectional area larger on the side opposite to the heat transfer space 53. As a result, it is possible to increase an amount of the fluid 55 stored in the heat transfer space 53 and the buffer space 54b.

Furthermore, according to the present embodiment, the heat transfer space 53 is formed into the ring shape in the circumferential direction of the base. As a result, it is possible to secure the area of contact between the cooling plate 14 and the upper electrode 18.

Furthermore, according to the present embodiment, the heat transfer space 53 is formed into a plurality of independent islands in the circumferential direction of the base. As a result, it is possible to form the heat transfer space, readily avoiding the connection portion between the channel 15 and the pipe 16 in the cooling plate 14, the gas supply port 13a, and the like.

The embodiments disclosed herein should be considered as illustrative and not restrictive in all respects. Various omissions, substitutions, and modifications may be made to the above described embodiments, without departing from the scope and gist of the appended claims.

In the above embodiment, the example of the plasma processing apparatus 1 using the capacitively coupled plasma as a plasma source to perform processing, such as etching, on the substrate W has been described, but the disclosed technology is not limited thereto. As long as an apparatus performing processing on the substrate W with plasma is used, the plasma source is not limited to the capacitively coupled plasma, and any plasma source, such as inductively coupled plasma, microwave plasma, or magnetron plasma may be used.

Furthermore, in the above embodiments, an example of the substrate processing apparatus has been described using the plasma processing apparatus 1, but is not limited thereto. For example, the present disclosure may be applied to a thermal chemical vapor deposition (CVD) apparatus that does not use plasma.

Furthermore, in the above embodiment, the heat transfer space 53 has been provided at the peripheral edge portion of the cooling plate 14, but the configuration of the heat transfer space 53 is not limited thereto. For example, according to a method of fixing the upper electrode 18 to the cooling plate 14, the heat transfer space 53 may be provided at a portion where the gap is generated due to deformation of the cooling plate 14. For example, when a gap is generated at a center part of the cooling plate 14, the heat transfer space 53 may be provided at the center part.

Furthermore, in the above embodiment, the heat transfer space 53 has been provided between the lower surface of the cooling plate 14 and the upper surface of the upper electrode 18, but the configuration of the heat transfer space 53 is not limited thereto. For example, when the cooling plate 14 is divided into the lower member 14a and the upper member 14b, the heat transfer space 53 may be provided between an upper surface of the lower member 14a and the lower surface of the upper member 14b.

In this configuration, the upper member 14b can be regarded as the base, and the lower member 14a can be regarded as a part of the upper electrode.

It is noted that the present disclosure can also have the following configurations.
(1)

An upper top plate arranged at an upper part of a chamber, the upper top plate comprising:
a base;
an upper electrode that is arranged on a lower surface side of the base; and
a thermally conductive medium that is filled in a heat transfer space being provided between a lower surface of the base and an upper surface of the upper electrode and being surrounded by a sealing member,
wherein
a buffer space communicating with the heat transfer space is formed on the lower surface of the base in contact with the heat transfer space, and
the thermally conductive medium is also partially filled in the buffer space.
(2)

The upper top plate according to (1), wherein
the thermally conductive medium includes a liquid substance.
(3)

The upper top plate according to (2), wherein
the thermally conductive medium includes a heat transfer sheet arranged in the heat transfer space.
(4)

The upper top plate according to (2) or (3), wherein
the liquid substance is a vacuum grease.
(5)

The upper top plate according to any one of (1) to (4), wherein
the buffer space is connected to an injection channel communicating with an outside of the base.
(6)

The upper top plate according to (5), wherein
the injection channel communicates with an inside of the chamber.
(7)

The upper top plate according to (6), wherein
the buffer space has an internal pressure that changes according to an internal pressure of the chamber.
(8)

The upper top plate according to any one of (1) to (7), wherein
the buffer space has a slit shape.
(9)

The upper top plate according to any one of (1) to (7), wherein
the buffer space has a hole shape.
(10)

The upper top plate according to (8) or (9), wherein
the buffer space is formed to have a cross-sectional area larger on a side of the heat transfer space.
(11)

The upper top plate according to (8) or (9), wherein
the buffer space is formed to have a cross-sectional area larger on a side opposite to the heat transfer space.
(12)

The upper top plate according to any one of (1) to (11), wherein
the heat transfer space is formed into a ring shape in a circumferential direction of the base.
(13)

The upper top plate according to any one of (1) to (11), wherein
the heat transfer space is formed into a plurality of independent islands in a circumferential direction of the base.
(14)

A substrate processing apparatus comprising:
a chamber; and
an upper top plate that is arranged at an upper part of the chamber,
wherein
the upper top plate includes:
a base;
an upper electrode that is arranged on a lower surface side of the base; and
a thermally conductive medium that is filled in a heat transfer space being provided between a lower surface of the base and an upper surface of the upper electrode and being surrounded by a sealing member,
in the base, a buffer space communicating with the heat transfer space is formed on the lower surface in contact with the heat transfer space, and
the thermally conductive medium is also partially filled in the buffer space.

According to the present disclosure, favorable thermal conduction can be maintained even when the base is deformed due to heat input.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is

1. An upper top plate arranged at an upper part of a chamber, the upper top plate comprising:
a base;
an upper electrode that is located on a lower surface side of the base; and
a thermally conductive medium that is in a heat transfer space that is located between a lower surface of the base and an upper surface of the upper electrode and being surrounded by a sealing structure,
wherein
a buffer space communicating with the heat transfer space is on the lower surface of the base in contact with the heat transfer space, and
the thermally conductive medium is also partially in the buffer space.

2. The upper top plate according to claim 1, wherein
the thermally conductive medium includes a liquid substance.

3. The upper top plate according to claim 2, wherein
the thermally conductive medium includes a heat transfer sheet located in the heat transfer space.

4. The upper top plate according to claim 2, wherein
the liquid substance is a vacuum grease.

5. The upper top plate according to claim 1, wherein
the buffer space is connected to an injection channel that communicates with an outside of the base.

6. The upper top plate according to claim 5, wherein
the injection channel communicates with an inside of the chamber.

7. The upper top plate according to claim 6, wherein
the buffer space has an internal pressure that changes according to an internal pressure of the chamber.

8. The upper top plate according to claim 1, wherein
the buffer space has a slit shape.

9. The upper top plate according to claim 1, wherein
the buffer space has a hole shape.

10. The upper top plate according to claim 8, wherein
the buffer space has a cross-sectional area larger on a side of the heat transfer space.

11. The upper top plate according to claim 9, wherein
the buffer space has a cross-sectional area larger on a side of the heat transfer space.

12. The upper top plate according to claim 8, wherein
the buffer space has a cross-sectional area larger on a side opposite to the heat transfer space.

13. The upper top plate according to claim 9, wherein
the buffer space has a cross-sectional area larger on a side opposite to the heat transfer space.

14. The upper top plate according to claim 1, wherein
the heat transfer space has a ring shape in a circumferential direction of the base.

15. The upper top plate according to claim 1, wherein
the heat transfer space has a plurality of independent islands in a circumferential direction of the base.

16. A substrate processing apparatus comprising:
a chamber; and
an upper top plate that is located at an upper part of the chamber,
wherein
the upper top plate includes:
a base;
an upper electrode that is located on a lower surface side of the base; and
a thermally conductive medium that is in a heat transfer space that is located between a lower surface of the base and an upper surface of the upper electrode and being surrounded by a sealing member,
in the base, a buffer space communicating with the heat transfer space is on the lower surface in contact with the heat transfer space, and
the thermally conductive medium is also partially in the buffer space.

17. The substrate processing apparatus of claim 16, wherein
the thermally conductive medium includes a liquid substance.

18. The substrate processing apparatus of claim 17, wherein
the thermally conductive medium includes a heat transfer sheet located in the heat transfer space.

19. The substrate processing apparatus of claim 17, wherein
the liquid substance is a vacuum grease.

20. The substrate processing apparatus of claim 16, wherein
the buffer space is connected to an injection channel that communicates with an outside of the base.
